(19) United States
(12) Patent Application Publication
(10) Pub. No.: US 2025/0079251 A1
(43) Pub. Date: Mar. 6, 2025

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Kai-Fung Chang, Taipei City (TW); Yi-Yang Lei, Taichung City (TW); Ching-Hua Hsieh, Hsinchu (TW)

(73) Assignee: Taiwan Semiconductor Manufacturing Company, Ltd., Hsinchu (TW)

(21) Appl. No.: 18/461,538

(22) Filed: Sep. 6, 2023

(51) Int. Cl. H01L 23/31; H01L 21/56; H01L 23/00; H01L 23/498; H01L 25/10

(52) U.S. Cl. CPC H01L 23/3192; H01L 21/568; H01L 23/3185; H01L 23/49827; H01L 24/16; H01L 24/19; H01L 24/20; H01L 25/105; H01L 21/6835; H01L 24/32; H01L 24/73; H01L 2221/68359; H01L 2221/68372; H01L 2221/68377; H01L 2224/16227; H01L 2224/19; H01L 2224/214; H01L 2224/215; H01L 2224/32225; H01L 2224/73204; H01L 2225/1041; H01L 2924/01013; H01L 2924/01028; H01L 2924/01029; H01L 2924/01046; H01L 2924/01047; H01L 2924/0105; H01L 2924/01079

(57) ABSTRACT

A semiconductor package includes a semiconductor die including die connectors, a first insulating encapsulant laterally covering the semiconductor die, a die attach film (DAF) overlying the first insulating encapsulant and the semiconductor die, and a redistribution structure overlying the DAF and the semiconductor die. The die connectors are laterally covered by the DAF, and the redistribution structure is electrically coupled to the die connectors.

### BACKGROUND

Semiconductor devices and integrated circuits used in a variety of electronic applications are typically manufactured from a semiconductor wafer. The semiconductor dies of the semiconductor wafer are processed and packaged with other electronic devices at the wafer level, and various technologies have been developed for wafer level packaging. Although existing semiconductor package and manufacturing method thereof have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A through 1F illustrate schematic cross-sectional views of intermediate steps during a process for forming a semiconductor package, in accordance with some embodiments.

FIGS. 2A through 2E illustrate schematic cross-sectional views of intermediate steps during a process for forming a semiconductor package, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

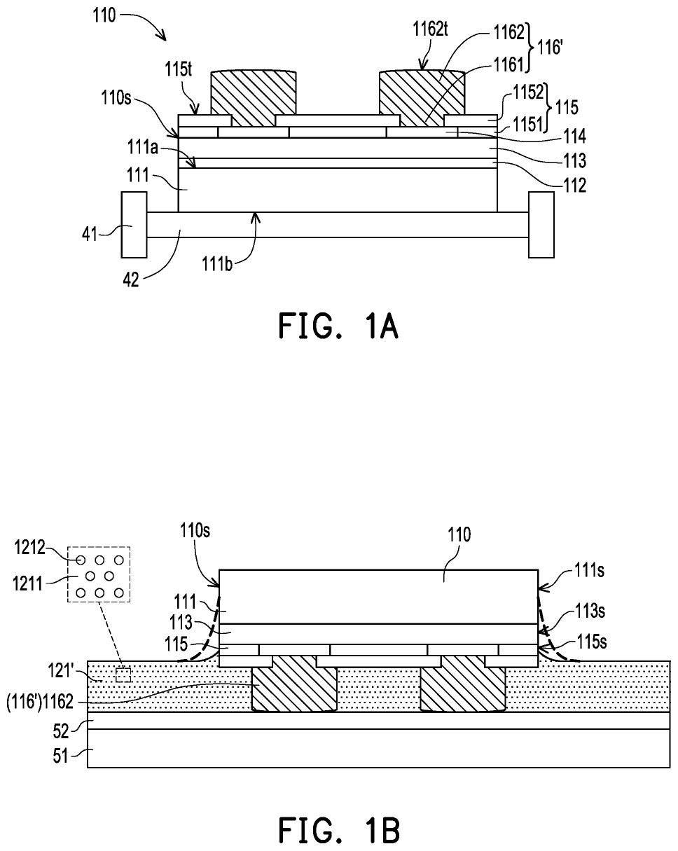

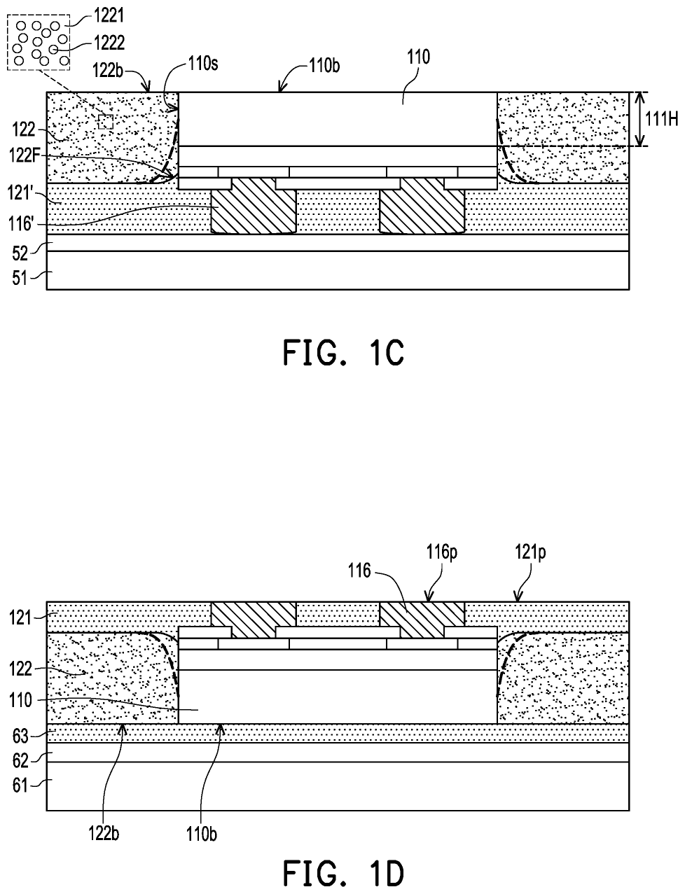

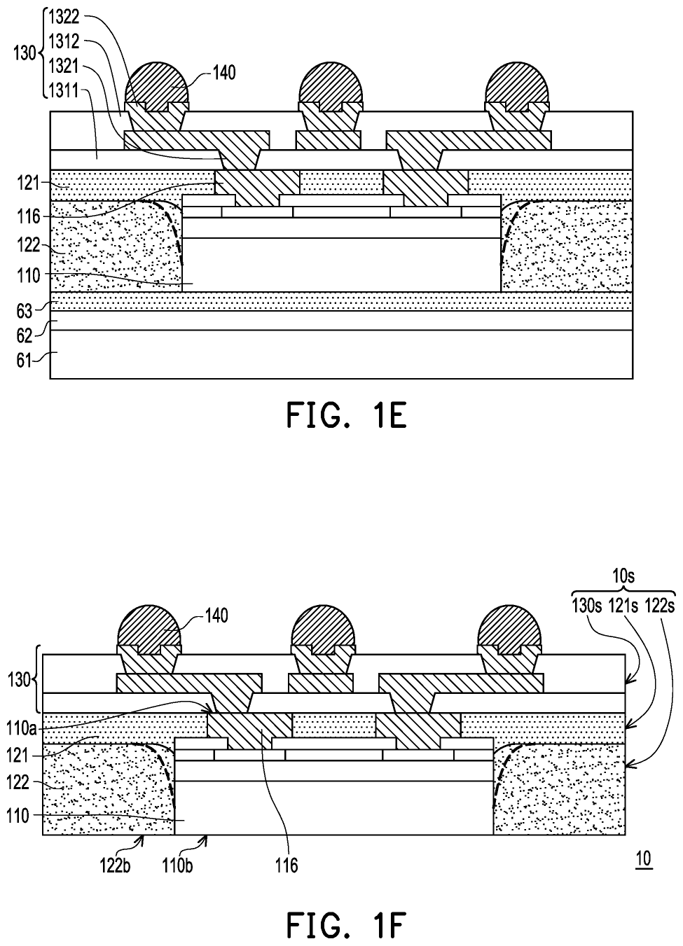

FIGS. 1A through 1F illustrate schematic cross-sectional views of intermediate steps during a process for forming a semiconductor package, in accordance with some embodiments. Although method embodiments are discussed as being performed in a particular order, other embodiments may be performed in any logical order.

Referring to FIG. 1A, a semiconductor die 110 is provided on a tape 42 supported by a frame 41. The semiconductor die 110 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. The semiconductor die 110 may be formed in a semiconductor wafer including die regions, and the die regions are singulated through a singulation process to form a plurality of semiconductor dies 110. Note that a single semiconductor die 110 is shown for illustrative purposes.

In some embodiments, the semiconductor die 110 includes a semiconductor substrate 111, such as silicon, doped or undoped, or an active layer of a semiconductor-on-insulator (SOI) substrate. The semiconductor substrate 111 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 111 may have an active surface 111a (e.g., a front side) and a rear surface 111b (e.g., a back side).

In some embodiments, the semiconductor die 110 includes a device layer 112 formed in/on the active surface 111a of the semiconductor substrate 111. For example, the device layer 112 includes a wide variety of active devices (e.g., transistors) and/or passive devices (e.g., capacitors, resistors, inductors) and the like that may be used to generate the desired structural and functional requirements of the design for the semiconductor die 110. The device layer 112 including the active devices and/or passive devices may be formed through front-end-of-line (FEOL) processes. The device layer 112 may be referred to as a FEOL layer. In some embodiments, the active devices and/or passive devices are covered by an inter-layer dielectric (ILD) layer, where the ILD layer may include one or more layers formed of dielectric materials such as Phospho-Silicate Glass (PSG), Boro-Silicate Glass (BSG), Boron-Doped Phospho-Silicate Glass (BPSG), undoped Silicate Glass (USG), the like, or combinations thereof.

With continued reference to FIG. 1A, the semiconductor die 110 may include an interconnect structure 113 which interconnects the devices of the device layer 112 to form an integrated circuit. For example, the interconnect structure 113 is formed through back-end-of-line (BEOL) processes. The interconnect structure 113 may be formed of alternating layers of dielectric (e.g., low-k dielectric material) and conductive material (e.g., copper) with vias interconnecting the layers of conductive material and may be formed through any suitable process (e.g., deposition, damascene, or the like). In some embodiments, the semiconductor die 110 includes conductive pads (e.g., aluminum pads, aluminum-copper pads, or the like) 114 formed on the interconnect structure 113. The conductive pads 114 may be electrically coupled to the devices of the device layer 112 through the conductive features (not individually shown) of the interconnect structure 113.

In some embodiments, the semiconductor die 110 includes a dielectric layer 115 formed on the interconnect structure 113 and surrounding each of the conductive pads 114, and at least a portion of the respective conductive pad 114 may be accessibly exposed by dielectric layer 115 for further electrical connection. The dielectric layer 115 may include a first sublayer 1151 formed on the interconnect structure 113 and laterally surrounding the conductive pads 114, and a second sublayer 1152 overlying the first sublayer 1151 and having openings accessibly exposing the conductive pads 114. In some embodiments, the first sublayer 1151 is a passivation film which may be formed from a dielectric material, such as silicon oxide, silicon nitride, the like, or combinations thereof. The second sublayer 1152 may be formed of a different dielectric material than the first sublayer 1151, such as polyimide (PI), polybenzoxazole (PBO), benzocyclobutene (BCB), or other polymeric material. For example, after performing the singulation process to form the individual semiconductor die 110, the sidewalls of the dielectric layer 115, the interconnect structure 113, and the semiconductor substrate 111 may be substantially leveled (or aligned) with one another to form the sidewall 110s of the semiconductor die 110.

Still referring to FIG. 1A, the semiconductor die 110 may include die connectors 116′ formed on the conductive pads 114. The die connectors 115 are electrically coupled to the devices of the device layer 112 through the conductive pads 114 and the interconnect structure 113. For example, the die connectors 116′ are conductive pillars (e.g., formed of a metal such as copper), extend through the openings in the dielectric layer 115 and are physically and electrically coupled to respective ones of the conductive pads 114. The respective die connector 116′ may include a bottom portion (e.g., via portion) 1161 disposed in the openings of the dielectric layer 115 and landing on the corresponding conductive pad 114, and a top portion 1162 overlying the bottom portion 1161 and extending on the top surface 115t of the dielectric layer 115. In some embodiments, the top surface 1162t of the respective top portion 1162 is not flat (e.g., convex curved) at this stage and will be planarized in the subsequent process for further electrical connection. It should be noted that the number of the die connectors 116′ and the number of the conductive pads 114 illustrated herein are merely examples and construe no limitation in the disclosure.

Referring to FIG. 1B and with reference to FIG. 1A, a die attach film (DAF) 121′ may be provided on a first temporary carrier 51, and the semiconductor die 110 may be picked and placed on the first temporary carrier 51. The first temporary carrier 51 may include any suitable material that may provide structural support for the subsequently-performed processes. For example, the first temporary carrier 51 include silicon (e.g., bulk silicon), metal (e.g., steel), glass, ceramic, combinations thereof, multi-layers thereof, or the like. The first temporary carrier 51 may be provided in a wafer form, a panel form, or a chip form, etc. In some embodiments, a first release layer 52 is interposed between the first temporary carrier 51 and the DAF 121′. The first release layer 52 may include a light-to-heat-conversion (LTHC) release coating which reduces or loses its adhesiveness when exposed to a radiation source (e.g., ultra-violet light or a laser). Alternatively, the first release layer 52 may be any acceptable adhesive material different from the material of the DAF.

In some embodiments, the DAF 121′ includes a base material 1211 which may be a polymeric material or the like. For example, the base material 1211 includes epoxy resin, phenol resin, or poly-olefin, etc., although alternatively, other dielectric materials compatible with semiconductor processing environments may be used. In some embodiments, the DAF 121′ includes fillers 1212 embedded in the base material 1211. The fillers 1212 may be formed of inorganic material such as silica, aluminum hydroxide, calcium carbonate, magnesium hydroxide, aluminum oxide, a combination thereof, or the like. It should be noted that fillers 1212 illustrated in spherical shape in FIG. 1B are merely examples, and other shapes of the fillers 1212 may be employed. In some embodiments, the viscosity of the DAF 121′ is lower than that of the dielectric layer 115 of the semiconductor die 110. In some embodiments, the DAF 121′ is an adhesive or may be referred to as an adhesive layer. The adhesive strength of the DAF 121′ with respect to the die connectors 116 is greater than the adhesive strength of the dielectric layer 115 with respect to the die connectors 116. The DAF 121′ may include curable material (e.g., any curable resin) and may be a thermosetting material that cures through the addition of energy, such as heat or irradiation, to a stronger form.

In some embodiments, the DAF 121′ is thick enough to bury the die connectors 116′ of the semiconductor die 110 therein. For example, the top portion 1162 of the respective die connector 116′ is laterally covered by the DAF 121′. The gap between adjacent ones of the die connectors 116′ may be filled with the DAF 121′. In some cases where the top surface 1162t of the respective die connector 116′ is convex curved, at least a portion of the top surface 1162t of the respective die connector 116′ is in physical contact with the first release layer 52. The DAF 121′ may fill the vertical gap between the top surface 1162t of the respective die connector 116′ and the first release layer 52. In such embodiment, the DAF 121′ may partially cover the top surface 1162t. The die connectors 116′ physically abutting against the first release layer 52 may be substantially aligned with one another.

In some embodiments, to bury the die connectors 1162 to the DAF 121′, heat is applied to the DAF 121′ while (or after) the semiconductor die 110 is placed over the first temporary carrier 51. The heat may be applied to activate the adhesive properties of the DAF 121′. For example, the DAF 121′ is adapted to include a semi-liquid adhesive when heated. The DAF 121′ may be a thick liquid when applied but forms a solid after a curing process. Conditions suitable for curing the DAF 121′ include subjecting the DAF 121′ to a curing temperature ranging from about 100° C. to about 200° C., for a duration ranging from about 300 seconds to about 7200 seconds. In some embodiments, pressure is also applied to the DAF 121′, e.g., from the first temporary carrier 51 upwardly to the semiconductor die 110, from the semiconductor die 110 downwardly to the first temporary carrier 51, or a combination thereof. When the DAF 121′ is returned to room temperature, the DAF 121′ may return to a solid, and the semiconductor die 110 may be securely positioned in its predetermined location over the first temporary carrier 51. In some embodiments, the DAF 121′ is partially cured at this stage.

Still referring to FIG. 1B, when placing the semiconductor die 110 over the first temporary carrier 51, a force (e.g., a capillary force, a compressive force, etc.) may draw a portion of the DAF 121′ upward between the adjacent semiconductor dies 110. For example, the DAF 121′ extends upward to cover at least a portion of the sidewall 110s of the semiconductor die 110. The DAF 121′ may cover the sidewall 115s of the dielectric layer 115, may extend further to cover the sidewall 113s of the interconnect structure 113, or may extend further to cover the sidewall 111s of the semiconductor substrate 111 as illustrated in the dashed lines. The DAF 121′ does not fully cover the sidewall 110s of the semiconductor die 110, for example, at least an upper portion of the sidewall 111s of the semiconductor substrate 111 may be accessibly exposed by the DAF 121′. The extending range of the DAF 121′ on the sidewall 110s of the semiconductor die 110 involves interacting variables, such as DAF's viscosity, surface topography of die, gap between dies, etc. The disclosure is not limited thereto.

Referring to FIG. 1C and with reference to FIG. 1B, an insulating encapsulant 122 may be formed over the first temporary carrier 51 to encapsulate the semiconductor die 110. The insulating encapsulant 122 may be an epoxy resin, a molding compound, a molding underfill, the like, or any suitable encapsulant material. In some embodiments, the insulating encapsulant 122 includes a base material 1221 and fillers 1222 embedded in the base material 1221. It should be noted that spherical fillers 1222 illustrated in FIG. 1C are merely examples, and other shapes of the fillers 1222 may be employed depending on product requirements. In some embodiments, a density of the fillers 1222 in the base material 1221 of the insulating encapsulant 122 is denser than that of the fillers 1212 in the base material 1211 of the DAF 121′. For example, the DAF 121′ has a smaller number of fillers 1212 per unit volume compared to the number of fillers 1222 in the insulating encapsulant 122. The DAF 121′ may have the high fluidity and the low viscosity, since the reciprocal of viscosity is fluidity. For example, under the same temperature/pressure conditions, the viscosity of the DAF 121′ is lower than the viscosity of the insulating encapsulant 122. The insulating encapsulant 122 may be formed by compression molding, transfer molding, or any acceptable technique.

In some embodiments, an encapsulant material is first formed on the DAF 121′ such that the semiconductor die 110 is buried in the encapsulant material, and then a curing process is performed to solidify the encapsulant material. In some embodiments, the curing process of the encapsulant material is performed at a temperature between about 100° C. and about 250° C. for duration between about 1800 seconds and about 14400 seconds. The curing temperature may be adjusted depending on the material of the insulating encapsulant 122. For example, the curing temperature of the encapsulant material is higher than the curing temperature of the DAF 121′. During the curing of the encapsulant material, the DAF 121′ may then be fully cured. In some embodiments, an interface 122F between the insulating encapsulant 122 and a portion of the DAF 121′ on the sidewall 110s of the semiconductor die 110 may be curved (e.g., concave toward the semiconductor die 110).

In some embodiments, a thinning process (e.g., chemical-mechanical polishing (CMP), grinding, etching, a combination thereof, or the like) is performed on the encapsulant material to remove excess portion of the encapsulant material on the rear surface 110b of the semiconductor die 110 so as to form the insulating encapsulant 122. In some embodiments, the semiconductor substrate 111 is thinned during the thinning process. The DAF 121′ may provide the structural and mechanical support during the thinning process, and the DAF 121′ may be referred to as a supporting layer. For example, a thickness 111H of the semiconductor substrate 111 is about 30 μm after the thinning process. The semiconductor die 110 may be viewed as an ultra-thin die. In some embodiments, the surface 122b of the insulating encapsulant 122 is substantially leveled (or coplanar) with the rear surface 110b of the semiconductor die 110, within process variations. During the thinning process, the die connectors 116′ may be physically abutted against the first release layer 52 and may be aligned with one another, thereby improving a total thickness variation (TTV) of the semiconductor die 110. For example, the TTV of the rear surface 110b of the semiconductor die 110 and/or the surface 122b of the insulating encapsulant 122 is about 6 μm or less, after the thinning process. Alternatively, the thinning process is skipped.

Referring to FIG. 1D and with reference to FIG. 1C, the semiconductor die 110 may be bonded to a second temporary carrier 61, and the first temporary carrier 51 may be de-bonded from the semiconductor die 110 and the DAF 121′. For example, the second temporary carrier 61 is provided with a second release layer 62. The second temporary carrier 61 and the second release layer 62 may be similar to the first temporary carrier 51 and the first release layer 52, respectively. In some embodiments, a sacrificial DAF 63 is attached to the rear surface 110b of the semiconductor die 110 and the surface 122b of the insulating encapsulant 122, and the sacrificial DAF 63 is disposed on the second release layer 62. For example, the sacrificial DAF 63 is attached to the rear surface 110b of the semiconductor die 110 and the surface 122b of the insulating encapsulant 122, and then the resulting structure is flipped upside down to be placed over the second temporary carrier 61. In some embodiments, the second temporary carrier 61 is provided with the second release layer 62 and the sacrificial DAF 63 overlying the second release layer 62, and the resulting structure illustrated in FIG. 1C is flipped upside down to be placed on the sacrificial DAF 63. The material of the sacrificial DAF 63 may be similar to the material of the DAF 121′. In some embodiments, the thickness of the sacrificial DAF 63 is less than that of the DAF 121′.

In some embodiments, the first temporary carrier 51 is removed from the semiconductor die 110 and the DAF 121′. In some cases where the first release layer 52 includes the LTHC layer, suitable light illumination may be applied to weaken the bonds of the LTHC layer so that the first temporary carrier 51 may be separated from the remaining structure. Alternatively, where the first release layer 52 is an adhesive layer, a suitable solvent may be used to dissolve the first release layer 52. In some other embodiments, the first temporary carrier 51 and the first release layer 52 are removed through stripping, peeling, etching, a combination thereof, etc. After removing the first temporary carrier 51 and the first release layer 52, the semiconductor die 110 and the DAF 121′ are accessibly exposed. In some embodiments, a planarization process (e.g., grinding, etching, a combination thereof, or the like) is performed on the semiconductor die 110 and the DAF 121′ to improve planarity for further processing. For example, the curved top surfaces 1162t (labeled in FIGS. 1A-1B) of the die connectors 116′ are planarized during the planarization process. The thicknesses of the DAF 121′ and the die connectors 116′ may be reduced after the planarization process. In some embodiments, the planarized surfaces 116p of the die connectors 116 are substantially leveled (or coplanar) with the planarized surface 121p of the DAF 121, within process variations. Alternatively, the planarization process is skipped.

Referring to FIG. 1E and with reference to FIG. 1D, a redistribution structure 130 may be formed on the semiconductor die 110 and the DAF 121. In some embodiments, the redistribution structure 130 includes dielectric layers 1311 and 1312 and conductive patterns 1321 and 1322, where the conductive patterns 1321 and 1322 are electrically coupled to the die connectors 116 of the semiconductor die 110. The material(s) of the dielectric layers 1311 and 1312 may be different from the material of the DAF 121. For example, the dielectric layers 1311 and 1312 are electrically insulating polymer materials such as PBO, PI, BCB, etc. In some embodiments, the DAF 121 functions as an adhesive mechanism to adhere the semiconductor die 110 to the dielectric layer 1311 of the redistribution structure 130. For example, the adhesive strength of the DAF 121 with respect to the semiconductor die 110 (or the dielectric layer 1311/insulating encapsulant 122) is larger than the adhesive strength of the dielectric layer 1311 with respect to the overlying dielectric layer 1312 (or the underlying DAF 121). The conductive patterns 1321 and 1322, referred to as redistribution lines, may include conductive pads, conductive lines, conductive vias, etc. The conductive patterns 1321 and 1322 may be formed from conductive material(s) such as solder, copper, aluminum, gold, nickel, silver, palladium, tin, alloy, the like, a combination thereof, etc.

The dielectric layer 1311 may be formed on the planarized surface 121p of the DAF 121 and the semiconductor die 110 and may have openings accessibly exposing at least a portion of the respective planarized surfaces 116p of the die connectors 116. Conductive vias of the conductive pattern 1321 may be formed in the openings of the dielectric layer 1311 and may be in physical and electrical contact with the planarized surfaces 116p of the die connectors 116. The dielectric layer 1312 may be formed on the dielectric layer 1311. The conductive pattern 1322 formed in/on the dielectric layer 1312 and connected to the conductive pattern 1321 may include under bump metallization (UBM) pads for further electrical connection. Since the redistribution structure 130 connected to the semiconductor die 110 reroutes the electrical signal of the semiconductor die 110 and expands wider than the size of the semiconductor die 110, the redistribution structure 130 may be referred to as a fan-out redistribution structure. The redistribution structure 130 is shown as an example having two layers of conductive patterns and two layers of dielectric layers. More or fewer dielectric layers and conductive patterns may be formed in the redistribution structure 130.

With continued reference to FIG. 1E, conductive terminals 140 may be formed on the conductive pattern 1322 (e.g., UBM pads). The conductive terminals 140 may include conductive material(s) such as solder, copper, aluminum, gold, nickel, silver, palladium, tin, alloy, the like, or a combination thereof. The conductive terminals 140 may be ball grid array (BGA) connectors, solder balls, metal pillars, controlled collapse chip connection (C4) bumps, micro-bumps, electroless nickel-electroless palladium-immersion gold (ENEPIG) bumps, or the like. In some embodiments, the conductive terminals 140 are formed by: forming a solder material on the UBM pads; and reflowing the solder material to shape the solder material into the desired bump shapes. In some embodiments, the conductive terminals 140 are metal pillars (e.g., copper pillars; not shown) which may be solder free and have substantially vertical sidewalls, and a metal cap layer (not shown) is optionally formed on the top of the respective metal pillar.

Referring to FIG. 1F and with reference to FIG. 1E, the second temporary carrier 61, the second release layer 62, and the sacrificial DAF 63 may be removed to accessibly expose the surface 122b of the insulating encapsulant 122 and the rear surface 110b of the semiconductor die 110. The de-bonding process of the second temporary carrier 61 and the second release layer 62 may be similar to the de-bonding process of the first temporary carrier 51 and the first release layer 52 described in FIG. 1D. After removing the second temporary carrier 61 and the second release layer 62, the sacrificial DAF 63 may be removed by any suitable process, e.g., etching or the like. A cleaning process is optionally performed to remove residues of the sacrificial DAF 63 on the insulating encapsulant 122 and the semiconductor die 110.

In some embodiments where the previous processes described in FIGS. 1B-1E are performed in a wafer form, a singulation process is performed by sawing or laser cutting along scribe lines (not shown) to form individual semiconductor packages 10. For example, the sidewall 130s of the redistribution structure 130, the sidewall 121s of the DAF 121, and the sidewall 122s of the insulating encapsulant 122 are substantially aligned with one another and may form the coterminous sidewall 10s of the semiconductor package 10. In some embodiments, the semiconductor package 10 is referred to as an integrated fan-out (InFO) package.

The presence of the DAF 121 on the active side 110a of the semiconductor die 110 is advantageous for several reasons. The DAF 121 may provide the active side 110a protection; e.g., each of the die connectors 116 of the semiconductor die 110 are laterally covered by the DAF 121, and at least a portion of the die edge (e.g., the sidewall 115s labeled in FIG. 1B) may be covered by the DAF 121. During the packaging process (e.g., the pick-and-place process described in FIG. 1B), the DAF 121 improves adhesion between the semiconductor die 110 and the first temporary carrier 51. The improved adhesion provided by the DAF 121 prevents the shift of the semiconductor die 110 during/after the pick and place process and the subsequent thermal processes. The DAF 121 may protect the sidewall of the semiconductor die 110, e.g., during the thinning step described in FIG. 1C or during further handling. Since the die connectors 116 are embedded in the DAF 121 and aligned with one another over the first temporary carrier 51 so as to provide larger process window, the TTV of the semiconductor die 110 may be improved/reduced after the thinning process (as described in FIGS. 1B-1C). The DAF 121 may have compatible thermal stability and chemical resistance to aqueous processing and other processing for the semiconductor package 10.

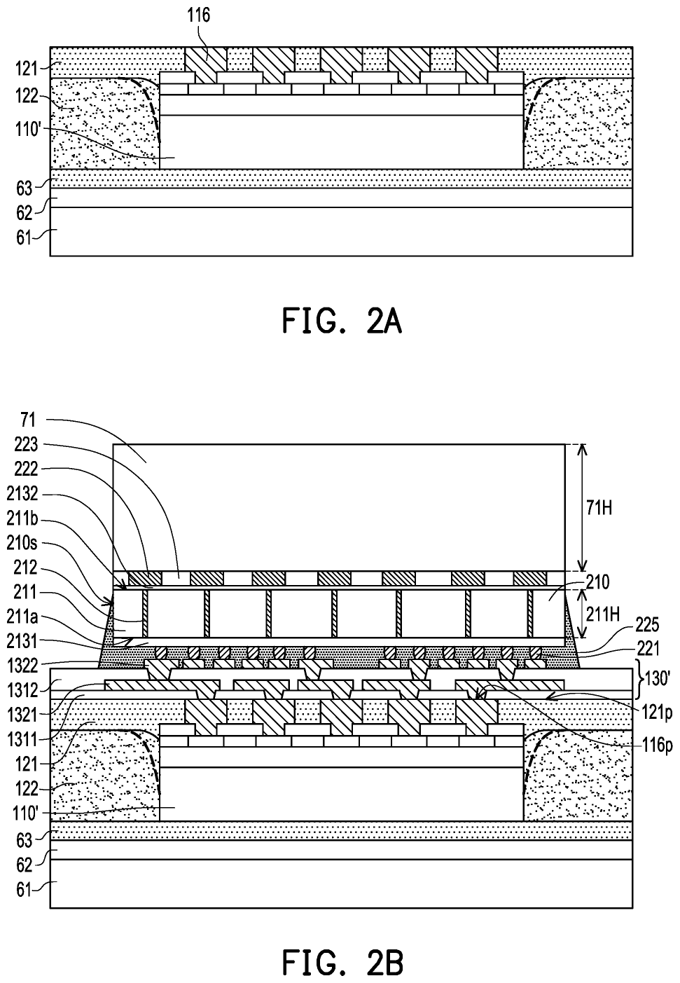

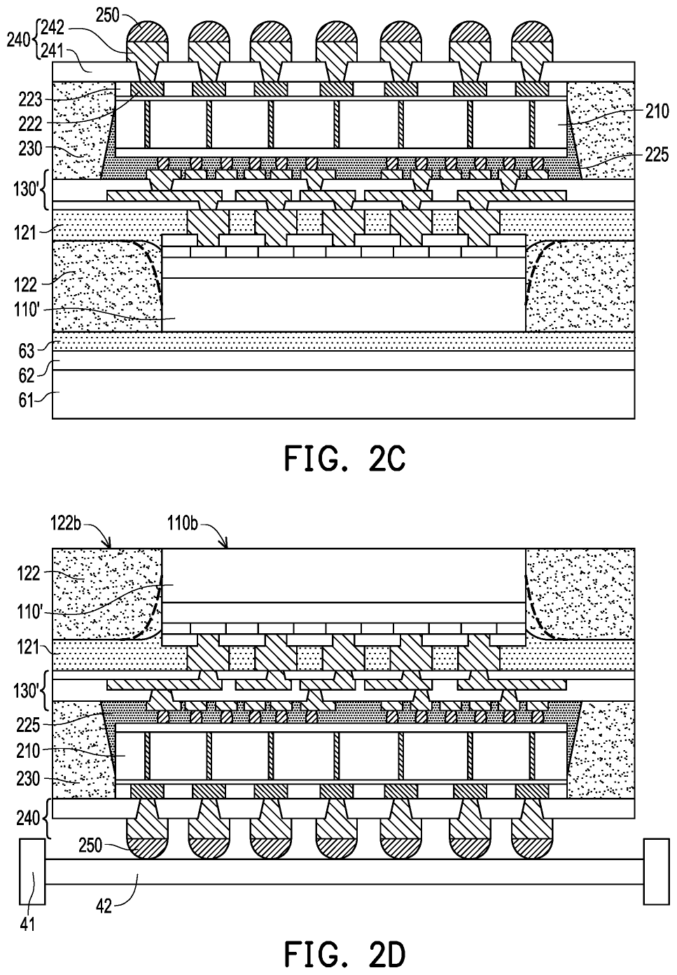

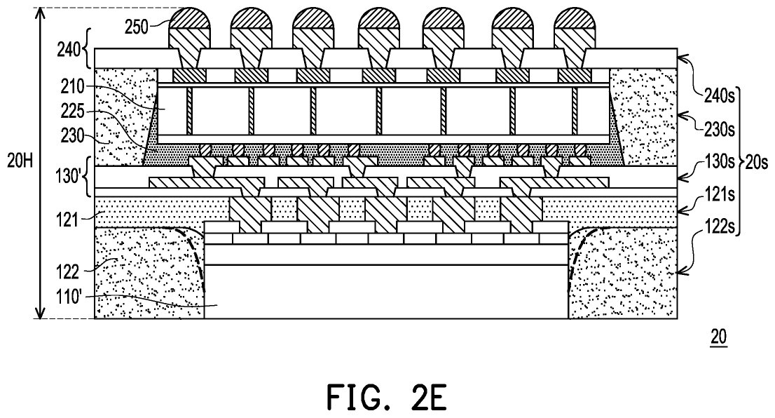

FIGS. 2A through 2E illustrate schematic cross-sectional views of intermediate steps during a process for forming a semiconductor package, in accordance with some embodiments. Unless specified otherwise, like reference numerals in this embodiment represent like components in the embodiment shown in FIGS. 1A through 1F formed by like processes, and only differences will be the focus of the following discussion. Accordingly, the processes and applicable materials may not be repeated herein.

Referring to FIG. 2A and with reference to FIG. 1D, the structure shown in FIG. 2A is similar to the structure shown in FIG. 1D, except for the number of the die connectors 116 of the semiconductor die 110′. The manufacturing processes and materials of the structure shown in FIG. 2A are similar to those of the structure shown in FIG. 1D, and therefore, the detailed descriptions are not repeated for the sake of brevity.

Referring to FIG. 2B and with reference to FIG. 2A and FIG. 1E, a first redistribution structure 130′ may be formed on the planarized surface 121p of the DAF 121 and the planarized surfaces 116p of the die connectors 116. A first redistribution structure 130′, similar to the redistribution structure 130 described in FIG. 1E, may include the dielectric layers 1311 and 1312 and the conductive patterns 1321 and 1322, where the conductive patterns 1321 and 1322 are electrically coupled to the die connectors 116 of the semiconductor die 110.

After the formation of the first redistribution structure 130′, an interposer 210 may be stacked upon and electrically coupled to the first redistribution structure 130′. The interposer 210 may be formed in a semiconductor wafer, which is singulated in the subsequent steps to form a plurality of interposers 210. The interposer 210 may be processed according to applicable manufacturing processes. For example, the interposer 210 includes a semiconductor substrate 211. In some embodiments, the semiconductor substrate 211 is similar to the semiconductor substrate 111 of the semiconductor die 110 described above with reference to FIG. 1A, and the description is not repeated herein. The interposer 210 may (or may not) include active and/or passive devices formed in the semiconductor substrate 211. In some embodiments, the interposer 210 includes through substrate vias (TSVs) 212 extending through the semiconductor substrate 211. The TSVs 212 may include a conductive material such as copper, copper alloy, or the like.

The interposer 210 may (may not) include one or more interconnect structure(s). In some embodiments, a first interconnect structure 2131 is formed on the first side 211a of the semiconductor substrate 211. In some embodiments, a second interconnect structure 2132 is formed on the second side 211b of the semiconductor substrate 211 opposite to the first side 211a. The TSVs 212 may be electrically and vertically connected to the first interconnect structure 2131 and the second interconnect structure 2132. The first and second interconnect structures 2131 and 2132, similar to the interconnect structure 113 of semiconductor die 110 described in FIG. 1A, may each include conductive features embedded in dielectric layers. In some embodiments, conductive joints 220 physically and electrically couple the first interconnect structure 2131 to the conductive pattern 1322 of the first redistribution structure 130′. The conductive joints 221 may include solder material and may be referred to as solder joints (or micro-bumps, in some embodiments). In some embodiments, conductive pads 222 may be formed on the second interconnect structure 2132 for further electrical connection. A dielectric layer 223 is optionally formed on the second interconnect structure 2132 to at least laterally cover the conductive pads 222. Alternatively, the second interconnect structure 2132 is omitted, the dielectric layer 223 is directly formed on the second side 211b of the semiconductor substrate 211, and the conductive pads 222 may land on the TSVs 212 in a one-to-one correspondence. It should be noted that the interposer 210 illustrated herein is merely an example, and the interposer 210 may be replaced with any suitable type of semiconductor die/package component.

With continued reference to FIG. 2B, the interposer 210 may be supported by a third temporary carrier 71 which is attached to the conductive pads 222 and the dielectric layer 223. The material of the third temporary carrier 71 may be similar to the first temporary carrier 51 described in FIG. 1B, and the size of the third temporary carrier 71 may be similar to that of the interposer 210. In some embodiments, a release layer (not shown; similar to the first release layer 52) is provided on the third temporary carrier 71, and the interposer 210 is attached to the third temporary carrier 71 through the release layer. The interposer 210 may be relatively thin, and the third temporary carrier 71 may provide structural and mechanical support during the formation of the conductive joints 221. For example, the third temporary carrier 71 has a thickness 71H that is more than ten times a thickness 211H of the semiconductor substrate 211. In some embodiments, the thickness 211H of the semiconductor substrate 211 is substantially equal to the thickness 111H of the semiconductor substrate 111 of the semiconductor die 110 described in FIG. 1C. Alternatively, the thickness 211H of the semiconductor substrate 211 is different from that of the semiconductor substrate 111.

Still referring to FIG. 2B, after coupling the interposer 210 to the first redistribution structure 130′, an underfill 225 may be formed in the gap between the interposer 210 and the first redistribution structure 130′ to at least surround the conductive joints 221 for protection. In some embodiments, the underfill 225 is dispensed on the dielectric layer 1312 of the first redistribution structure 130′ and covers the conductive joints 221 and the portion of the conductive pattern 1322 directly coupled to the conductive joints 221. The underfill 225 may extend to cover at least a portion of the sidewall 210s of the interposer 210, depending on the applied amount of the underfill 225. In some embodiments, the underfill 225 is formed by a capillary flow process after the interposer 210 is attached or may be formed by a suitable deposition method before the interposer 210 is attached. Alternatively, the underfill 225 is omitted, and the second insulating encapsulant 230 (labeled in FIG. 2C; e.g., molding underfill) may fill the gap between the interposer 210 and the first redistribution structure 130′.

Referring to FIG. 2C and with reference to FIG. 2B, the third temporary carrier 71 may be de-bonded from the interposer 210. The de-bonding process of the third temporary carrier 71 may be similar to the de-bonding process of the first temporary carrier 51 described in FIG. 1D. After the removal of the third temporary carrier 71, the interposer 210 may be accessibly exposed. In some embodiments, an insulating encapsulant 230 is formed on the first redistribution structure 130′ to laterally cover the interposer 210 and the underfill 225. The forming process and the material of the insulating encapsulant 230 may be similar to those of the insulating encapsulant 122 described in FIG. 1C. In some embodiments, a layer of encapsulating material is formed on the first redistribution structure 130′ to bury the interposer 210 and the underfill 225 (if exist), and then a thinning process (e.g., CMP, grinding, etching, a combination thereof, or the like) may be performed on the encapsulating material until at least a portion of the conductive pads 222 is accessibly exposed. For example, after the thinning process, the surfaces of the conductive pads 222, the dielectric layer 223, and the insulating encapsulant 230 are substantially leveled (or coplanar) with one another, within process variations. The insulating encapsulants 122 and 230 may be viewed as a first insulating encapsulant 122 and a second insulating encapsulant 230, respectively.

In some embodiments, a second redistribution structure 240 is formed on the interposer 210 and the second insulating encapsulant 230. The second redistribution structure 240 may include a dielectric layer 241 and a conductive pattern 242, where the conductive pattern 242 is electrically coupled to the interposer 210. The materials of the dielectric layer 241 and the conductive pattern 242 may be similar to the dielectric layers (1311/1312) and the conductive patterns (1321/1322), respectively. For example, the dielectric layer 241 is formed on the second insulating encapsulant 230 and the dielectric layer 223, and openings of the dielectric layer 241 accessibly expose portions of the conductive pads 222. The via portions of the conductive pattern 242 may be formed in the openings of the dielectric layer 241 and land on the conductive pads 222, and the pad portions of the conductive pattern 242 overlying the via portions may extend on the top surface of the dielectric layer 241. The conductive pattern 242 may (or may not) reroute the electrical signal of the interposer 210 and may (or may not) expand wider than the distribution of the conductive pads 222. Although a single layer of the dielectric layer 241 and a single layer of the conductive pattern 242 are illustrated, the second redistribution structure 240 may include more dielectric layers and conductive patterns according to some embodiments.

With continued reference to FIG. 2C, conductive terminals 250 may be formed on the conductive pattern 242 of the second redistribution structure 240. In some embodiments, the conductive terminals 250 are formed by forming a solder material on the conductive pattern 242 and reflowing the solder material to shape the solder material into the desired bump shapes. The conductive terminals 250 may be C4 bumps, BGA connectors, solder balls, metal pillars, ENEPIG bumps, or the like. In some embodiments, the structure is probed to determine whether the structure is defective or not. The probing may be performed by putting a probe card that includes probe pins into contact the conductive terminals 250 to determine electrical performance of the resulting structure. The probing may be performed prior to the reflow of the solder material, and after the probing, the reflow process is performed on those known good structure to shape the conductive terminals 250.

Referring to FIG. 2D and with reference to FIG. 2C, the resulting structure of FIG. 2C may be flipped upside down and may be placed on the tape 42 supported by the frame 41. The second temporary carrier 61, the second release layer 62, and the sacrificial DAF 63 may be removed to accessibly expose the surface 122b of the insulating encapsulant 122 and the rear surface 110b of the semiconductor die 110. The de-bonding process of the second temporary carrier 61 and the second release layer 62 may be similar to the process of de-bonding the first temporary carrier 51 and the first release layer 52 described in FIG. 1D. After removing the second temporary carrier 61 and the second release layer 62, the sacrificial DAF 63 may be removed by any suitable process e.g., etching or the like. A cleaning process is optionally performed to remove residues of the sacrificial DAF 63.

Referring to FIG. 2E and with reference to FIG. 2D, in some embodiments where the previous processes described in FIGS. 2A-2D are performed in a wafer form, a singulation process is performed to form individual semiconductor packages 20. For example, the sidewall 240s of the second redistribution structure 240, the sidewall 230s of the second insulating encapsulant 230, the sidewall 130s of the first redistribution structure 130′, the sidewall 121s of the DAF 121, and the sidewall 122s of the first insulating encapsulant 122 are substantially aligned with one another and may form the coterminous sidewall 20s of the semiconductor package 20.

The semiconductor package 20 may include the thin die (e.g., the semiconductor die 110) and the thin interposer (e.g., the interposer 210) stacked upon one another. It is challenging to handle such ultra-thin die/interposer while maintain the reduced TTV. By providing the first temporary carrier 51 with the thick DAF 121′ and embedding the die connectors 116 of the semiconductor die 110 in the DAF 121′ (e.g., the process described in FIG. 1B), the semiconductor die 110 may remain at the predetermined location during the molding process and the thinning process. Since the DAF 121 provides the improved adhesion between the semiconductor die 110 and the first temporary carrier 51, the die connectors 116 of the semiconductor die 110 surrounded by the DAF 121 may remain in place and aligned with one another. The TTV of the semiconductor die 110 may be improved (or reduced) after the thinning process. The interposer 210 may be attached to the third temporary carrier 71 when coupling the interposer 210 to the first redistribution structure 130′ (e.g., the process described in FIG. 2B), the third temporary carrier 71 may act as a structural support at this step, thereby reducing the likelihood of damage to the thin interposer. The overall thickness 20H of the semiconductor package 20 may be relatively thin while the TTV of the semiconductor package 20 is decreased. For example, the overall thickness 20H may be about 150 μm, and the TTV of the semiconductor die 110 is about 6 μm or less.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor package includes semiconductor package includes a semiconductor die including die connectors, a first insulating encapsulant laterally covering the semiconductor die, a die attach film (DAF) overlying the first insulating encapsulant and the semiconductor die, and a redistribution structure overlying the DAF and the semiconductor die. The die connectors are laterally covered by the DAF, and the redistribution structure is electrically coupled to the die connectors.

According to some alternative embodiments, a semiconductor package includes a first semiconductor die, a first insulating encapsulant laterally surrounding the first semiconductor die, an adhesive layer disposed on the first insulating encapsulant and the first semiconductor die, and a redistribution structure. An active surface of the first semiconductor die is substantially leveled with a top surface of the adhesive layer, and a rear surface of the first semiconductor die opposite to the active surface is substantially leveled with a bottom surface of the first insulating encapsulant. The redistribution structure is disposed on the adhesive layer and the active surface of the first semiconductor die, and the redistribution structure is electrically coupled to the first semiconductor die.

According to some alternative embodiments, a manufacturing method of a semiconductor package includes: embedding die connectors of a semiconductor die in a die attach film (DAF); forming an encapsulant material layer on the DAF to bury the semiconductor die; thinning a back side of the semiconductor die and the encapsulant material layer to form a first insulating encapsulant laterally covering the semiconductor die; and forming a redistribution structure on the die connectors and the DAF.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a semiconductor die comprising die connectors;
a first insulating encapsulant laterally covering the semiconductor die;
a die attach film (DAF) overlying the first insulating encapsulant and the semiconductor die, the die connectors being laterally covered by the DAF; and
a redistribution structure overlying the DAF and the semiconductor die, the redistribution structure being electrically coupled to the die connectors.

2. The semiconductor package of claim 1, wherein surfaces of the DAF and the die connectors are substantially leveled.

3. The semiconductor package of claim 1, wherein a portion of the DAF extends to cover at least a portion of a sidewall of the semiconductor die.

4. The semiconductor package of claim 1, wherein sidewalls of the DAF and the first insulating encapsulant are substantially leveled.

5. The semiconductor package of claim 1, wherein the semiconductor die further comprises a dielectric layer laterally covering via portions of the die connectors, and an adhesive strength of the DAF with respect to the die connectors is greater than that of the dielectric layer with respect to the die connectors.

6. The semiconductor package of claim 1, wherein a viscosity of the DAF is lower than that of the first insulating encapsulant.

7. The semiconductor package of claim 1, wherein a density of fillers of the DAF is lower than a density of fillers of the first insulating encapsulant.

8. The semiconductor package of claim 1, further comprising:
an interposer disposed on and electrically coupled to the redistribution structure; and
a second insulating encapsulant disposed on the redistribution structure and laterally covering the interposer.

9. The semiconductor package of claim 8, wherein sidewalls of the DAF, the first insulating encapsulant, and the second insulating encapsulant are substantially leveled.

10. The semiconductor package of claim 8, wherein the interposer is electrically coupled to the redistribution structure through solder joints.

11. A semiconductor package, comprising:
a first semiconductor die;
a first insulating encapsulant laterally surrounding the first semiconductor die;
an adhesive layer disposed on the first insulating encapsulant and the first semiconductor die, where an active surface of the first semiconductor die is substantially leveled with a top surface of the adhesive layer, and a rear surface of the first semiconductor die opposite to the active surface is substantially leveled with a bottom surface of the first insulating encapsulant; and
a redistribution structure disposed on the adhesive layer and the active surface of the first semiconductor die, the redistribution structure being electrically coupled to the first semiconductor die.

12. The semiconductor package of claim 11, wherein at least a portion of the adhesive layer extends to cover a sidewall of the first semiconductor die that is connected to the rear surface.

13. The semiconductor package of claim 11, wherein the first semiconductor die comprises die connectors at the active surface, and the adhesive layer laterally covers each of the die connectors.

14. The semiconductor package of claim 11, further comprising:
a second semiconductor die disposed on and electrically coupled to the redistribution structure; and
a second insulating encapsulant disposed on the redistribution structure and encapsulating the second semiconductor die.

15. A manufacturing method of a semiconductor package, comprising:
embedding die connectors of a semiconductor die in a die attach film (DAF);
forming an encapsulant material layer on the DAF to bury the semiconductor die;
thinning a back side of the semiconductor die and the encapsulant material layer to form a first insulating encapsulant laterally covering the semiconductor die; and
forming a redistribution structure on the die connectors and the DAF.

16. The manufacturing method of claim 15, wherein a curing temperature of the DAF is lower than that of the encapsulant material layer.

17. The manufacturing method of claim 15, wherein after embedding the die connectors of the semiconductor die in the DAF, a portion of the DAF extends to cover at least a portion of a sidewall of the semiconductor die.

18. The manufacturing method of claim 15, further comprising:
performing a planarization process on the die connectors and the DAF before forming the redistribution structure on the die connectors and the DAF.

19. The manufacturing method of claim 15, further comprising:
coupling an interposer to the redistribution structure through solder joints; and
forming a second insulating encapsulant on the redistribution structure to cover the interposer.

20. The manufacturing method of claim 19, further comprising:
providing the interposer with a temporary carrier, wherein the temporary carrier acts as a structural support when coupling the interposer to the redistribution structure; and
releasing the temporary carrier from the interposer before forming the second insulating encapsulant.
